(19) United States
(12) Patent Application Publication
(10) Pub. No.: US 2023/0327655 A1
(43) Pub. Date: Oct. 12, 2023

(54) DEVICE INCLUDING A COMPARATOR UNIT AND METHOD FOR OPERATING A DEVICE INCLUDING A COMPARATOR UNIT

(71) Applicant: Robert Bosch GmbH, Stuttgart (DE)

(72) Inventors: Taha Ibrahim Ibrahim Soliman, Renningen (DE); Tobias Kirchner, Ludwigsburg (DE)

(21) Appl. No.: 18/297,579

(22) Filed: Apr. 7, 2023

(30) Foreign Application Priority Data
Apr. 12, 2022 (DE) 10 2022 203 685.9

(51) Int. Cl. H03K 5/24; G06F 17/16

(52) U.S. Cl. CPC H03K 5/24; G06F 17/16; H03M 1/12

(57) ABSTRACT

A device including a first comparator unit, the first comparator unit including a first reference current provision unit for providing a first reference current and a first comparison current provision unit for providing a first comparison current, and the first comparator unit being designed to compare the first reference current with the first comparison current in order to obtain a first comparison result and, based on the first comparison result, to influence at least one reference current and/or at least one comparison current of at least one further comparator unit.

### CROSS REFERENCE

The present application claims the benefit under 35 U.S.C. § 119 of German Patent Application No. DE 10 2022 203 685.9 filed on Apr. 12, 2022, which is expressly incorporated herein by reference in its entirety.

### FIELD

The present invention relates to a device including a comparator unit.

The present invention further relates to a method for operating a device including a comparator unit.

### SUMMARY

Exemplary specific embodiments of the present invention relate to a device that includes a first comparator unit, the first comparator unit including a first reference current provision unit for providing a first reference current and a first comparison current provision unit for providing a first comparison current, and the first comparator unit being designed to compare the first reference current with the first comparison current in order to obtain a first comparison result and, based on the first comparison result, to influence at least one reference current and/or at least one comparison current of at least one further comparator unit.

In further exemplary specific embodiments of the present invention, the device may, for example, be used to implement a stage, for example, a comparator stage, for an analog-to-digital converter unit. For example, multiple stages, for example, comparator stages, may be provided in further exemplary specific embodiments for the analog-to-digital converter unit, each of the stages including, for example, at least one device according to the specific embodiments.

In further exemplary specific embodiments of the present invention, it is provided that the device includes at least one first influencing unit, which is designed to influence the at least one reference current and/or the at least one comparison current of the at least one further comparator unit, the at least one first influencing unit including at least one controllable current sink (or current source, for example, in the event of an “inversion” of a circuit implementing the device). In further exemplary specific embodiments, a comparison of the reference current with the comparison current of the at least one further comparator unit is influenceable as a result based on the first comparison result, for example.

In further exemplary specific embodiments of the present invention, it is provided that the first comparator unit is designed to output a first output signal based on the first comparison result. The first output signal, which characterizes, for example, a binary signal or the first comparison result, may, for example, be used to form a bit of a binary output signal of the analog-to-digital converter unit when using the device optionally also for a multi-stage analog-to-digital converter unit.

In further exemplary specific embodiments of the present invention, it is provided that the first comparator unit is designed to divert, for example, with the aid of a or of the first influencing unit, at least one predefinable current from a circuit node associated with the at least one reference current and/or with the at least one comparison current of at least one further comparator unit based on the first comparison result, as a result of which, in further exemplary specific embodiments, for example, a comparison of the respective at least one further comparator unit is influenceable, for example, in order to influence one or multiple less significant bits in a state change of a more significant bit of an analog-to-digital converter unit that includes the comparator units.

In further exemplary specific embodiments of the present invention, it is provided that the device includes at least one second comparator unit, the second comparator unit including a second reference current provision unit for providing a second reference current and a second comparison current provision unit for providing a second comparison current, and the second comparator unit being designed to compare the second reference current with the second comparison current in order to obtain a second comparison result and, based on the second comparison result, to influence at least one reference current and/or at least one comparison current of at least one further comparator unit, for example, based on the second comparison result, to divert at least one predefinable current from a circuit node associated with the at least one reference current and/or the at least one comparison current of at least one further comparator unit. In further exemplary specific embodiments, this makes it possible, for example, to provide a, for example, two-stage analog-to-digital converter unit, a first stage, for example, corresponding to a most significant bit (MSB) being implementable, for example, with the aid of the first comparator unit, and a second stage, for example, corresponding to a least significant bit (LSB) being implementable, for example, with the aid of the second comparator unit.

In further exemplary specific embodiments of the present invention, analog-to-digital converter units including more than two stages or bits, for example, including four or more stages, are also providable based on the device according to exemplary specific embodiments.

In further exemplary specific embodiments of the present invention, it is provided that the device includes n number, n=1, 2, 3, . . . of comparator units, each of the n number of comparator units including in each case a reference current provision unit for providing a respective reference current and in each case a comparison current provision unit for providing a respective comparison current, and each of the n number of comparator units being designed to compare a respective reference current with a respective comparison current in order to obtain a respective comparison result and, based on the respective comparison result, to output a respective output signal characterizing the respective comparison result.

In further exemplary specific embodiments of the present invention, it is provided that at least some, for example, n−1 many, comparator units of the n number of comparator units are designed to compare a respective reference current with a respective comparison current in order to obtain a respective comparison result and, based on the respective comparison result, to influence at least one reference current and/or at least one comparison current of at least one further comparator unit, which is associated, for example, with a less significant stage or a less significant bit during an exemplary use in a converter unit.

In further exemplary specific embodiments of the present invention, it is provided that a kth comparator unit, k=1, . . . , n−1 of the n number of comparator units is designed to influence at least one reference current and/or at least one comparison current of at least one further comparator unit of the n number of comparator units, for example, of an nth comparator unit, for example, based on the kth comparison result.

In further exemplary specific embodiments of the present invention, it is provided that the kth comparator unit, k=1, . . . , n−1 of the n number of comparator units includes a kth influencing unit, which is designed to influence the at least one reference current and/or the at least one comparison current of the at least one further comparator unit, the kth influencing unit, for example, including a controllable current sink (or a current source, for example, in the event of an “inversion” of a circuit implementing the device).

In further exemplary specific embodiments of the present invention, it is provided that the controllable current sink includes a series connection made up of at least one first transistor and a switch, for example, a semiconductor switch, for example, a second transistor.

In further exemplary specific embodiments of the present invention, it is provided that the first transistor and/or the second transistor is/are designed as a field effect transistor, for example, as a MOSFET, for example, as an N-channel MOSFET or as a P-channel MOSFET. In further exemplary specific embodiments, the drain-source paths of the first transistor and of the second transistor, for example, are then serially connected in accordance with the series connection described by way of example above.

In further exemplary specific embodiments of the present invention, it is provided that the first transistor and/or the second transistor is/are designed as a bipolar transistor, for example, an NPN- or PNP-type bipolar transistor. In further exemplary specific embodiments, the collector-emitter paths of the first transistor and of the second transistor, for example, are then serially connected in accordance with the series connection described by way of example above.

Instead of the first transistor and/or the second transistor, a (for example, different) controllable current source or a controllable electrical resistance may, for example, also be provided in each case in further exemplary specific embodiments of the present invention.

In further exemplary specific embodiments of the present invention, it is provided that the series connection is connected between a or between the circuit node associated with the at least one reference current and/or the at least one comparison current of the at least one further comparator unit and a reference potential.

In further exemplary specific embodiments of the present invention, it is provided that the switch is controllable based on the comparison result, for example, in order to activate or to deactivate the influencing of the at least one reference current and/or of the at least one comparison current of the at least one further comparator unit.

In further exemplary specific embodiments of the present invention, it is provided that the series connection includes a parallel connection made up of first transistors, which are connected in series to the switch.

In further exemplary specific embodiments of the present invention, it is provided that one transistor each of the parallel connection is assigned in each case to one further, for example, in each case other comparator unit, for example, in order to divert current from the further comparator unit based on a or on the comparison result of a comparator unit including the parallel connection.

In further exemplary specific embodiments of the present invention, it is provided that a compensation unit is provided to compensate for a voltage drop at at least one of the switches.

In further exemplary specific embodiments of the present invention, it is provided that a kth reference current provision unit is part of a first current mirror unit, for example, of a 1 to n current mirror unit including one input and n number of outputs.

In further exemplary specific embodiments of the present invention, it is provided that the first current mirror unit supplies, for example, multiple of the comparator units in each case with a corresponding reference current, when using the multiple comparator units for an analog-to-digital converter unit, for example, different comparator units of the multiple comparator units being suppliable with a different reference current, the reference current for a particular comparator unit being based, for example, on a significance of the respective comparator unit with respect to the analog-to-digital converter unit.

In further exemplary specific embodiments of the present invention, the first current mirror unit may, for example, be designed as a current mirror unit including one input and n number of outputs, a reference current, for example, a base reference current, being feedable to the first current mirror unit via its input, and the first current mirror unit outputting at its n number of outputs, for example, an nth reference current, for example, a base reference current, diverted in each case from the reference current.

In further exemplary specific embodiments of the present invention, it is provided that a kth comparison current provision unit is part of a second current mirror unit, for example, of a 1 to n current mirror unit including one input and n number of outputs.

In further exemplary specific embodiments of the present invention, it is provided that the second current mirror unit supplies, for example, multiple of the comparator units each with a corresponding comparison current. In further exemplary specific embodiments, the second current mirror unit may be designed, for example, as a current mirror unit including one input and n number of outputs, an input current, for example, an (analog, i.e., for example, time-continuous and value-continuous) input current to be transformed into a digital output signal, for example, being feedable to the second current mirror unit via its input, and the second current mirror unit outputting at its n number of outputs, for example, in each case an nth comparison current diverted from the input current.

Further exemplary specific embodiments of the present invention relate to an analog-to-digital converter unit, for example, a current-based or current-driven analog-to-digital converter, including at least one device according to the specific embodiments, the converter unit being designed to receive an input current and to form a digital output signal based on the input current.

In further exemplary specific embodiments of the present invention, it is provided that the converter unit is designed, based on a reference current, to form at least the first or an nth reference current, for example, with the aid of a or of the first current mirror unit, a current intensity of the nth reference current, for example, corresponding to a significance of the nth stage of the converter unit.

In further exemplary specific embodiments of the present invention, it is provided that the converter unit is designed to form at least the first or the nth comparison current based on the input current, for example, with the aid of a or of the second current mirror unit, a current intensity of the nth comparison current, for example, corresponding to a significance of the nth stage of the converter unit.

Further exemplary specific embodiments of the present invention relate to a method for operating a device including a first comparator unit, the first comparator unit including a first reference current provision unit and a first comparison current provision unit, the method including: providing a first reference current with the aid of the first reference current provision unit, providing a first comparison current with the aid of the first comparison current provision unit, comparing the first reference current with the first comparison current in order to obtain a first comparison result, and, based on the first comparison result, influencing at least one reference current and/or at least one comparison current of at least one further comparator unit, and, optionally outputting a first output signal based on the first comparison result.

Further exemplary specific embodiments of the present invention relate to a processing unit, for example, for ascertaining a scalar product, for example, a vector matrix multiplier, for example, a dot product engine including a matrix of elements with a controllable electrical resistance, and at least one analog-to-digital converter unit according to the specific embodiments.

Further exemplary specific embodiments of the present invention relate to a use of the device according to the specific embodiments and/or of the analog-to-digital converter unit according to the specific embodiments and/or the method according to the specific embodiments and/or of the processing unit according to the specific embodiments for at least one of the following elements: a) converting a current into a binary value, b) executing a binary coding, c) providing a, for example, fully, current-driven analog-to-digital converter.

Further features, possible applications and advantages of the present invention result from the following description of exemplary embodiments of the present invention, which are represented in the figures. All features described or represented in this case, alone or in arbitrary combination, form the subject matter of the present invention, regardless of their wording or representation in the description or in the figures.

### BRIEF DESCRIPTION OF THE DRAWINGS

FIG. 1 schematically shows a simplified block diagram according to exemplary specific embodiments of the present invention.

FIG. 2 schematically shows a simplified block diagram according to exemplary specific embodiments of the present invention.

FIG. 3 schematically shows a simplified block diagram according to exemplary specific embodiments of the present invention.

FIG. 4 schematically shows a simplified block diagram according to exemplary specific embodiments of the present invention.

FIG. 5 schematically shows a simplified flowchart according to exemplary specific embodiments of the present invention.

FIG. 6 schematically shows a simplified flowchart according to exemplary specific embodiments of the present invention.

FIG. 7 schematically shows a simplified circuit diagram according to exemplary specific embodiments of the present invention.

FIG. 8 schematically shows a simplified block diagram according to exemplary specific embodiments of the present invention.

FIG. 9 schematically shows aspects of uses according to exemplary specific embodiments of the present invention.

### DETAILED DESCRIPTION OF EXAMPLE EMBODIMENTS

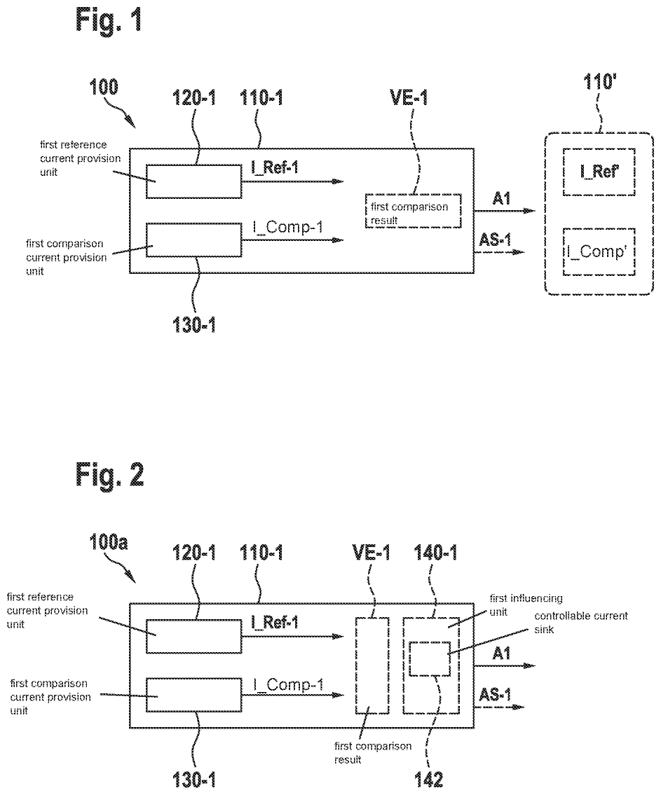

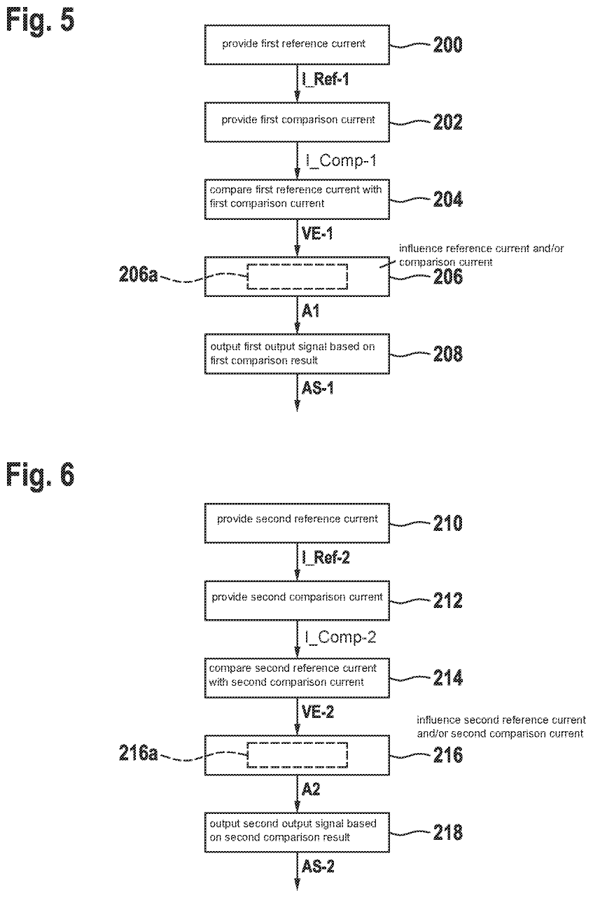

Exemplary specific embodiments, cf. for example FIGS. 1 and 5, relate to a device 100 including a first comparator unit 110-1, first comparator unit 110-1 including a first reference current provision unit 120-1 for providing 200 (FIG. 5) a first reference current I_Ref-1 and a first comparison current provision unit 130-1 for providing 202 a first comparison current I_Comp-1, and the first comparator unit 110-1 being designed to compare first reference current I_Ref-1 with first comparison current I-Comp-1, see block 204 according to FIG. 5, in order to obtain a first comparison result VE-1 and, based on first comparison result VE-1, to influence at least one reference current I-Ref′ and/or at least one comparison current I-Comp′ of at least one further comparator unit 110′, see block 206 according to FIG. 5 and arrow A1 according to FIG. 1 and FIG. 5. In further exemplary specific embodiments, the influencing 206 may include, for example, a diverting 206a of at least one predefinable current from a circuit node associated with the at least one reference current I-Ref′ and/or at least one comparison current I_Comp′.

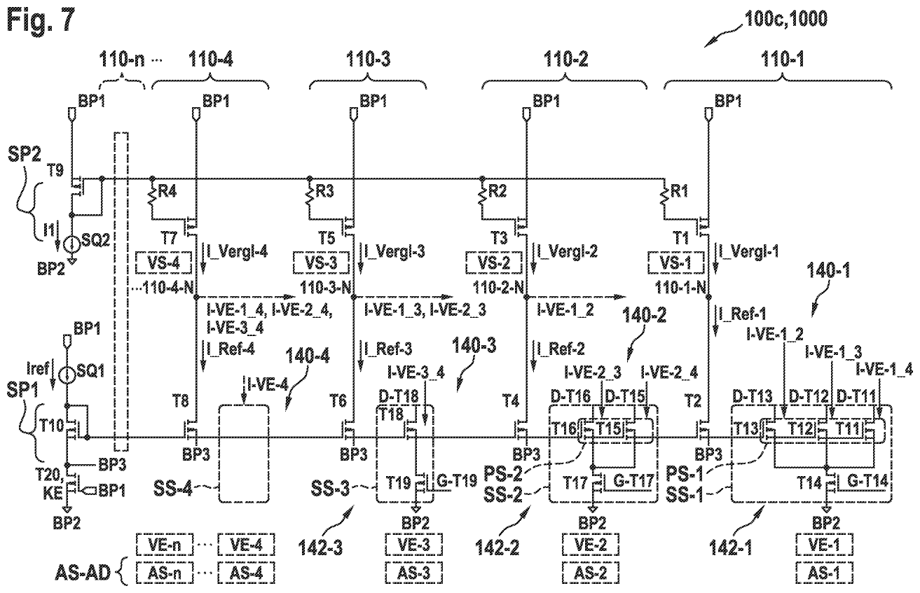

In further exemplary specific embodiments, FIG. 1, device 100 may, for example, be used to implement a stage, for example a comparator stage, for an analog-to-digital converter unit 1000, see, for example, FIG. 7. In further exemplary specific embodiments, for example, multiple stages, for example comparator stages, may be provided for analog-to-digital converter 1000, each of the stages including, for example, at least one device according to the specific embodiments or analog-to-digital converter unit 1000 (FIG. 7) including, for example, a device 100c that includes multiple comparator units (110-1, 110-2, 110-3, 110-4, . . . , 110-n).

In further exemplary specific embodiments, FIG. 2, it is provided that device 100a includes at least one first influencing unit 140-1, which is designed to influence the at least one reference current I-Ref′ (FIG. 1) and/or the at least one comparison current I_Comp′ of the at least one further comparator unit 110′, the at least one first influencing unit 140-1 (FIG. 2) including at least one controllable current sink 142 (or at least one controllable current source, for example, in the event of an “inversion” possible according to further exemplary specific embodiments, see below, of a circuit implementing device 100a). In further exemplary specific embodiments, a comparison of reference current I_Ref′ with comparison current I_Comp′ of the at least one further comparator unit 110′ is influenceable as a result, for example, based on first comparison result VE-1.

In further exemplary specific embodiments, FIGS. 1, 2, it is provided that first comparator unit 110-1 is designed to output a first output signal AS-1 based on first comparison result VE-1, see also block 208 according to FIG. 5. First output signal AS-1, which characterizes a binary signal or first comparison result VE-1, may be used, for example, to form a bit of a binary output signal AS-AD (FIG. 7) of analog-to-digital converter unit 1000, for example, when using device 100, 100a for an optionally also multi-stage analog-to-digital converter unit 1000 (FIG. 7).

In further exemplary specific embodiments, FIG. 2, it is provided that first comparator unit 110-1 is designed to divert, for example, with the aid of a or the first influencing unit 140-1, at least one predefinable current from a circuit node associated with the at least one reference current I_Ref′ and/or the at least one comparison current I_Comp′ of at least one further comparator unit 110′ based on first comparison result VE-1, as a result of which in further exemplary specific embodiments, for example, a comparison of the respective at least one further comparator unit 110′ is influenceable, for example, in order to influence one or multiple less significant bits, for example, all less significant bits, in a state change of a more significant bit of an analog-to-digital converter that includes comparator units 110-1, 110′.

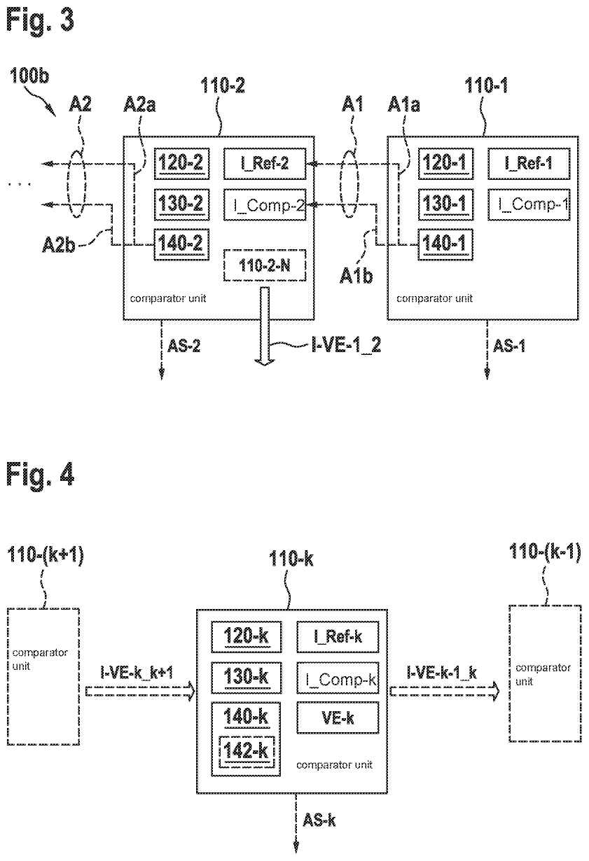

In further exemplary specific embodiments, FIG. 3, it is provided that device 100b includes at least one second comparator unit 110-2, second comparator unit 110-2 including a second reference current provision unit 120-2 for providing a second reference current I_Ref-2 and a second comparison current provision unit 130-2 for providing a second comparison current I_Comp-2, and second comparator unit 110-2 being designed to compare second reference current I_Ref-2 with second comparison current I_Comp-2 in order to obtain a second comparison result VE-2 and, based on second comparison result VE-2, to influence at least one reference current and/or at least one comparison current of at least one further comparator unit, see arrows A2a, A2b or collectively A2 according to FIG. 3, for example, based on second comparison result VE-2, to divert at least one predefinable current from a circuit node associated with the at least one reference current and/or with the at least one comparison current of at least one further comparator unit (not shown in FIG. 3, see the dots “. . . ” to the left in FIG. 3), for example, with the aid of a second influencing unit 140-2. In further exemplary specific embodiments, this makes it possible to provide a, for example, two-stage or multi-stage analog-to-digital converter unit, a first stage, for example, corresponding to a most significant bit (MSB), being implementable, for example, with the aid of first comparator unit 110-1, and a second stage, for example, corresponding to a least significant bit (LSB), being implementable, for example, with the aid of second comparator unit 110-2. Further comparator stages are also possible in further exemplary specific embodiments, see the dots “. . . ” to the left in FIG. 3.

Arrows A1a, A1b, identified collectively in FIG. 3 with A1, symbolize the influencing of at least reference current I_Ref-2 and/or of at least comparison current I_Comp-2 of at least second comparator unit 110-2. For example, a current I_VE-1_2 is divertible from a circuit node 110-2-N of the second comparator unit 110-2 with the aid of first influencing unit 140-1, for example, based on first comparison result VE-1, second comparison current I_Comp-2 being feedable to circuit node 110-2-N with the aid of second reference current provision unit 120-2 and second comparison current I_Comp-2 being divertible from circuit node 110-2-N with the aid of second comparison current provision unit 130-2. As is apparent, influencing A1, A1a, A1b of at least one of currents I_Comp-2, I_Ref-2 in further exemplary specific embodiments may influence second comparison result VE-2. Based on second comparison result VE-2, second comparator unit 110-2, for example, may also output a second output signal AS-2. Further details regarding circuit node 110-2-N according to further exemplary specific embodiments are described further below with reference to FIG. 7.

FIG. 6 schematically shows exemplary aspects of an operation of second comparator unit 110-2 (FIG. 3), blocks 210, 212, 214, 216, 216a, 218 corresponding respectively to blocks 200, 202, 204, 206, 206a, 208 according to FIG. 5, described with respect to first comparator unit 110-1. If in further exemplary specific embodiments, for example, more than two comparator units are present, for example, n number of comparator units, the aspects depicted by way of example in FIGS. 5, 6 are applicable accordingly also to one or to multiple, for example, at least k number, for example, where k=n−1, of further comparator units.

In further exemplary specific embodiments, analog-to-digital converter units including more than two stages or bits, for example, including four or more stages are, for example, also providable based on device 100, 100 [sic], 100b according to exemplary specific embodiments.

In further exemplary specific embodiments, FIG. 4, it is provided that device 100, 100a, 100b, 100c includes n number, n=1, 2, 3, . . . of comparator units, each of the n number of comparator units including in each case a reference current provision unit for providing a respective reference current, and in each case a comparison current provision unit for providing a respective comparison current, and each of the n number of comparator units being designed to compare a respective reference current with a respective comparison current in order to obtain a respective comparison result and, based on the respective comparison result, to output a respective output signal characterizing the respective comparison result.

This is shown by way of example in FIG. 4, based on a kth comparator unit 110-k of the n number of comparator units. Elements 120-k, 130-k, 140-k, I_Ref-k, I_Comp-k, AS-k of kth comparator unit 110-k correspond, for example, to respective elements 120-1, 130-1, 140-1, I_Ref-1, I_Comp-1, AS-1 of first comparator unit 110-1.

In FIG. 4, for example, a first further, namely (k+1)th comparator unit 110-(k+1), and a second further, namely (k−1)th comparator unit 110-(k−1) are symbolically depicted. Block arrow I-VE-k−1_k symbolizes a current, which is derivable with the aid of comparator unit 110-(k−1) based on its comparison result, for example, from a circuit node (not shown) of kth comparator unit 110-k, for example, in order to influence the comparison of the kth comparator unit 110-k. Block arrow I-VE-k_k+1 symbolizes a current, which is derivable with the aid of comparator unit 110-k based on its comparison result VE-k, for example, from a circuit node (not shown) of the (k+1)th comparator unit 119-(k+1), for example, in order to influence the comparison of the (k+1)th comparator unit 110-(k+1).

FIG. 7 schematically shows a circuit diagram of a device 100c according to further specific embodiments, which includes four comparator units 110-1, 110-2, 110-3, 110-4 represented in relative detail as well as, optionally, further, for example up to a total of n number of comparator units, the optionally present further comparator units in FIG. 7 being symbolized for the sake of clarity by optional block 110-n.

In further exemplary specific embodiments, see FIG. 7, it is provided that at least some, for example n−1 number, of comparator units 110-1, 110-2, 110-3 of the n number of comparator units are designed to compare a respective reference current with a respective comparison current in order to obtain a respective comparison result and, based on the respective comparison result, to influence at least one reference current and/or at least one comparison current of at least one further comparator unit, which is associated in an exemplary use in a converter unit, for example, with a less significant stage or a less significant bit.

In further exemplary specific embodiments, it is provided that a kth comparator unit, k=1, . . . , n−1 of the n number of comparator units, described by way of example below as exemplified by k=1, is designed to influence at least one reference current I_Ref-2 and/or at least one comparison current I_Comp_2 of at least one further comparator unit 110-2 of the n number of comparator units, for example, based on kth comparison result VE-1.

In further exemplary specific embodiments, first comparison result VE-1 is formed, for example, by first comparison current I_Comp-1 being fed to a circuit node 110-1-N of first comparator unit 110-1 with the aid of first comparison current provision unit 130-1 and by first reference current I_Ref-1 being diverted from circuit node 110-1-N of first comparator unit 110-1 with the aid of first reference current provision unit 120-1, as a result of which an electrical potential of circuit node 110-1-N of first comparator unit 110-1 characterizes first comparison result VE-1, which in further exemplary specific embodiments is usable, for example, also as first output signal AS-1 or for forming first output signal AS-1, for example, with the aid of an optional buffer circuit or amplifier circuit VS-1, which amplifies the electrical potential of circuit node 110-1-N of first comparator unit 110-1.

In further exemplary specific embodiments, it is provided that the kth, in the present example, first (k−1), comparator unit 110-1 of the n number of comparator units includes a first influencing unit 140-1, which is designed to influence the at least one reference current and/or the at least one comparison current of the at least one further comparator unit 110-2, 110-3, 110-4, first influencing unit 140-1, for example, including a controllable current sink (or a current source, for example, in the event of an “inversion” of a circuit implementing the device) 142-1.

In further exemplary specific embodiments, it is provided that controllable current sink 142-1 includes a series connection SS-1 made up of at least one first transistor T11, T12, T13 and a switch, for example, a semiconductor switch, for example, a second transistor, T14.

In further exemplary specific embodiments, it is provided that first transistor T11, T12, T13 and/or second transistor T14 is/are designed as a field effect transistor, for example, a MOSFET, for example, as an N-channel MOSFET or as a P-channel MOSFET. In further exemplary specific embodiments, the drain-source paths of the first transistor and of the second transistor, for example, are then serially connected in accordance with the series connection SS-1 described by way of example above.

In further exemplary specific embodiments, it is provided that the first transistor and/or the second transistor is/are designed, as a bipolar transistor, for example, as an NPN- or PNP-type bipolar transistor. In further exemplary specific embodiments, the collector emitter paths of the first transistor and of the second transistor are then serially connected in accordance with the series connection described by way of example above.

Instead of the first transistor and/or the second transistor, a (for example, different) controllable current source or a controllable electrical resistance may, for example, also be provided in each case in further exemplary specific embodiments.

In further exemplary specific embodiments, it is provided that series connection SS-1 is connected between a or between the circuit node 110-2-N associated with the at least one reference current I_Ref-2 and/or the at least one comparison current I_Comp-2 of the at least one further comparator unit 110-2 and a reference potential BP2.

In further exemplary specific embodiments, it is provided that switch T14 is controllable based on comparison result VE-1, for example, in order to activate or to deactivate influencing 206 (FIG. 5) of the at least one reference current and/or of the at least one comparison current of the at least one further comparator unit 110-2, 110-3 . . . . For example, in some specific embodiments, a gate electrode G-T14 of the switch may be acted upon by the electrical potential of circuit node 110-1-N or by first output signal AS-1.

In further exemplary specific embodiments, it is provided that series connection SS-1 includes a parallel connection PS-1 made up of first transistors T11, T12, T13, which are connected in series to switch T14.

In further exemplary specific embodiments, it is provided that one transistor T11, T12, T13 each of parallel connection PS-1 is assigned in each case to one further, for example, in each case to another comparator unit 110-2, 110-3, 110-4, for example, to divert current from the further comparator unit or units based on a or on the FIRST comparison result VE-1 of a comparator unit 110-1 including parallel connection PS-1.

In the present case, for example, a drain electrode D-T13 of transistor T13 is connected to circuit node 110-2-N in order to divert a predefinable current I-VE-1_2 based on first comparison result VE-1 from circuit node 110-2-N during an activation of current sink 142-1 with the aid of switch T14. In the present case, for example, a drain electrode D-T12 of transistor T12 is connected to circuit node 110-3-N in order to divert a predefinable current I-VE-1_3 based on first comparison result VE-1 from circuit node 110-3-N during an activation of current sink 142-1 with the aid of switch T14. In the present case, for example, a drain electrode D-T11 of transistor T11 is connected to circuit node 110-4-N in order to divert a predefinable current I-VE-1_4 based on first comparison result VE-1 from circuit node 110-4-N during an activation of current sink 142-1 with the aid of switch T14. This is also schematically symbolized in FIG. 7 by the dashed-line arrows, which point away to the right in FIG. 7 from respective circuit nodes 110-2-N, 110-3-N, 110-4-N.

Second comparator unit 110-2 includes a second influencing unit 140-2 that includes a current sink (or a current source, for example, in the event of an “inversion” of a circuit implementing the device) 142-2, which includes a series connection SS-2. Series connection SS-2 has a function and structure comparable to series connection SS-1, including a parallel connection PS-2 of two transistors T15, T16 and a switch T17, for example, for the selective activation or deactivation of a diversion of currents from further comparator stages 110-3, 110-4, for example, based on a second comparison result VE-2. In further exemplary specific embodiments, it is provided, for example, that switch T17 is controllable based on comparison result VE-2, for example, in order to activate or to deactivate influencing 206 (FIG. 5) of the at least one reference current and/or of the at least one comparison current of the at least one further comparator unit 110-3, 110-4, . . . . For example, in some exemplary specific embodiments, a gate electrode G-T17 of switch T17 may be acted upon by the electrical potential of circuit node 110-2-N or by second output signal AS-2.

In the present case, for example, a drain electrode D-T16 of transistor T16 of series connection SS-2 is connected to circuit node 110-3-N in order to divert a predefinable current I-VE-2_3 based on second comparison result VE-2 from circuit node 110-3-N during an activation of current sink 142-2 with the aid of switch T17. In the present case, for example, a drain electrode D-T15 of transistor T15 is connected to circuit node 110-4-N in order to divert a predefinable current I-VE-2_4 based on second comparison result VE-2 from circuit node 110-4-N during an activation of current sink 142-2 with the aid of switch T17.

Third comparator unit 110-3 includes a third influencing unit 140-3, including a current sink (or a current source, for example, in the event of an “inversion” of a circuit implementing the device) 142-3, which includes a series connection SS-3. Series connection SS-3 has a function and structure comparable to series connection SS-1, SS-2, including a transistor T18 and a switch T19, for example for the selective activation or deactivation of a diversion of currents from further comparator stages 110-3, . . . , for example based on a third comparison result VE-3. In further exemplary specific embodiments, it is provided, for example, that switch T19 is controllable based on comparison result VE-3, for example, in order to activate or to deactivate influencing 206 (FIG. 5) of the at least one reference current and/or of the at least one comparison current of the at least one further comparator unit 110-4, . . . .

In some specific embodiments, for example, a gate electrode G-T19 of switch T19 may be acted upon by the electrical potential of circuit node 110-3-N or by third output signal AS-3.

In the present case, for example, a drain electrode D-T18 of transistor T18 of series connection SS-3 is connected to circuit node 110-4-N in order to divert a predefinable current I-VE-3_4 based on third comparison result VE-3 from circuit node 110-4-N during an activation of current sink 142-3 with the aid of switch T19.

In an exemplary number of a total of n=4 comparator units, 110-1, 110-2, 110-3, 110-4, fourth comparator unit 110-4 in further exemplary specific embodiments requires no influencing unit 140-4, since converter unit 1000, for example, includes no further less significant stage whose circuit node would have to be influenced. If, however, more than, for example, n=4 comparator units are provided, fourth comparator unit 110-4 may also include an influencing unit 140-4, for example, including a corresponding series connection SS-4, for example, in order to influence circuit nodes of further less significant stages of converter unit 1000.

It is apparent that in further specific embodiments, depending on the number of further less significant stages optionally to be influenced, one or multiple first transistors (for example, similar to transistor T18 for stage 110-4) as well as an associated switch, for example, in the form of a second transistor (for example, similar to transistor T19 for stage 110-4) may be provided in further comparator units 110-4, . . . .

Similarly, in further exemplary specific embodiments, influencing units 140-1, 140-2, . . . of the more significant stages 110-1, 110-2, . . . of converter unit 1000 may also be expanded. If, for example, converter unit 1000 includes n=8 stages, influencing unit 140-1 may, for example, include a controllable current sink 142-1, whose series connection SS-1, includes, for example, a total of n−1 number of, i.e., in the present case, for example, seven, first transistors (similar to transistors T11, T12, T13) in order to selectively, for example, by controlling switch T14, divert from circuit nodes 110-2-N, 110-3-N, . . . of the seven less significant stages 110-2, 110-3, . . . 110-8 (not shown) respective currents of circuit nodes 110-2-N, 110-3-N, . . . of the seven less significant stages 110-2, 110-3, . . . 110-8 (not shown) based on first comparison result VE-1.

It is similarly the case in further specific embodiments, for example, also for influencing units 140-2, 140-3, . . . of more significant stages 110-2, 110-3, . . . of converter unit 1000. If converter unit 1000 as described above includes, for example, a total of n=8 number of stages, influencing unit 140-2 may, for example, include a controllable current sink 142-2, whose series connection SS-2 includes, for example, a total of n−2 number of, i.e., in the present case, for example, six, first transistors (similar to transistors T15, T16) in order to selectively, for example, by controlling switch T17, divert from circuit nodes 110-3-N, 110-4-N, . . . of the six less significant stages 110-3, 110-4, . . . 110-8 (not shown) with respect to second stage 110-2 respective currents of circuit nodes 110-3-N, 110-4-N, . . . of the six less significant stages 110-3, 110-4, . . . 110-8 (not shown), etc., based on second comparison result VE-2.

In further exemplary specific embodiments, FIG. 7, it is provided that a kth reference current provision unit, k =1, . . . , n is part of a first current mirror unit SP1, for example, of a 1-to-n current mirror unit SP1 including one input and n number of outputs.

In further exemplary specific embodiments, it is provided that first current mirror unit SP1 supplies, for example, multiple of comparator units 110-1, 110-2, 110-3, 110-4, . . . in each case with a corresponding reference current I_Ref-1, I_Ref-2, I_Ref-3, I_Ref-4, . . . , different comparator units of the multiple comparator units being providable with a different reference current I_Ref-1, I_Ref-2, I_Ref-3, I_Ref-4, . . . , for example, when using the multiple comparator units 110-1, 110-2, 110-3, 110-4, . . . for a or for the analog-to-digital converter unit 1000, the reference current for a particular comparator unit being based, for example, on a significance or stage of respective comparator unit 110-1, 110-2, 110-3, 110-4, . . . with respect to analog-to-digital converter unit 1000.

In further exemplary specific embodiments, first current mirror unit SP1 may, for example, be designed as a current mirror unit including one input (transistor T10) and n number of outputs (transistors T2, T4, T6, T8), a reference current, for example, a base reference current, Iref, being feedable to first current mirror unit SP1 via its input T10, for example, with the aid of a current source SQ1, and first current mirror unit SP1 outputting at its n number of outputs T2, T4, T6, T8, for example, in each case an nth reference current I_Ref-1, I-Ref-2, I_Ref-3, I_Ref-4 diverted from the reference current, for example, from base reference current Iref.

In further exemplary specific embodiments, it is provided that a compensation unit KE, for example, in the form of a transistor T20, is provided to compensate for a voltage drop at at least one of switches T14, T17, T19.

In further exemplary specific embodiments, FIG. 7, it is provided that a kth comparison current provision unit is part of a second current mirror unit SP2, for example, of a 1 to n current mirror unit SP2 including one input (for example, transistor T9) and n number of outputs (for example, transistors T1, T3, T5, T7).

In further exemplary specific embodiments, it is provided that second current mirror unit SP2 supplies, for example, multiple of comparator units 110-1, 110-2, 110-3, 110-4, . . . in each case with a corresponding comparison current I_Comp-1, I_Comp-2, I_Comp-3, I_Comp-4. In further exemplary specific embodiments, second current mirror unit SP2 may be designed, for example, as a current mirror unit including an input T9 and n number of outputs T1, T3, T5, T7, an input current I1, for example, an (analog, i.e., for example, time-continuous or value-continuous) input current to be transformed into a digital output signal AS-AD being feedable to second current mirror SP2 via its input T9, and second current mirror SP2 outputting at its n number of outputs T1, T3, T5, T7, . . . , for example, in each case an nth comparison current I_Comp-1, I_Comp-2, I_Comp-3, I_Comp-4 diverted from input current I1.

In further exemplary specific embodiments, the load paths (for example, drain-source paths) of transistors T1, T2 are connected between a first reference potential BP1 (for example, operating voltage potential) and a third reference potential BP3 (for example, a ground potential). In further exemplary specific embodiments, the load paths (for example, drain-source paths) of switches T14, T17, T19 are connected between first transistors T11, T12, T13 or T15, T16 or first transistor T18 and a second reference potential BP2.

Further exemplary specific embodiments relate to an analog-to-digital converter unit 1000, for example, a current-based or current-driven analog-to-digital converter unit, including at least one device 100c according to the specific embodiments, converter unit 1000 being designed to receive an input current I1 and to form a digital output signal AS-AD based on input current I1.

In further exemplary specific embodiments, it is provided that converter unit 1000 is designed to form at least the first or an nth reference current based on a reference current Iref, for example, with the aid of a or of the first current mirror unit SP1, a current intensity of the nth reference current corresponding, for example, to a significance of the nth stage of converter unit 1000.

In further exemplary specific embodiments, it is provided that converter unit 1000 is designed to form at least the first or the nth comparison current based on input current I1, for example, with the aid of a or of the second current mirror unit SP2, a current intensity of the nth comparison current corresponding, for example, to a significance of the nth stage of converter unit 1000.

Further exemplary aspects and specific embodiments are described below, each of which are combinable individually or in combination with one another in further exemplary specific embodiments with at least one of the above-described specific embodiments.

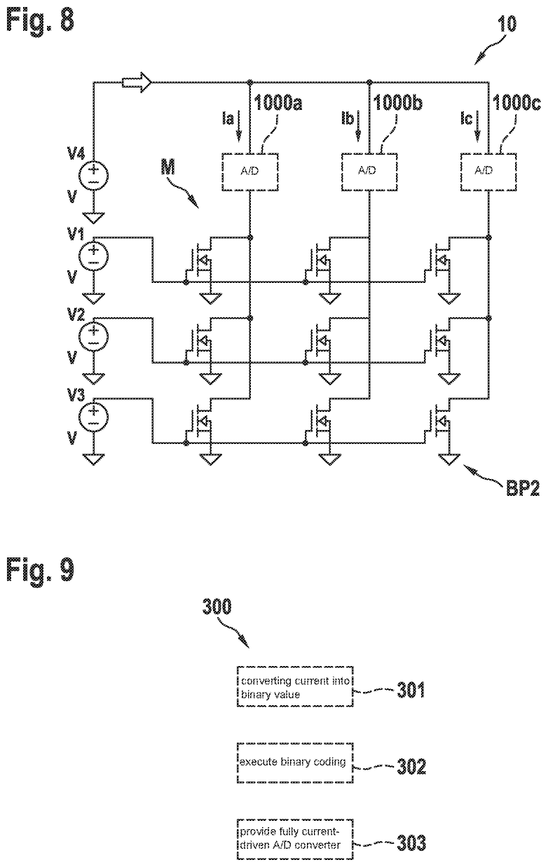

In further exemplary specific embodiments, FIG. 7, input current I1 may be provided, for example, by matrix M according to FIG. 8, for example, as current Ia according to FIG. 8.

In further exemplary specific embodiments, FIG. 7, each comparator unit 110-1, 110-2, . . . of device 100c is associated with a bit of converter unit 1000. Starting from, for example, a total of n=4 stages or bits, comparator unit 110-4 is associated, for example, with the LSB (least significant bit), and an electrical potential at circuit node 110-4-N characterizes a state of the LSB, and comparator unit 110-1 is associated with the MSB (most significant bit), and an electrical potential at circuit node 110-1-N characterizes a state of the MSB.

In further exemplary specific embodiments, transistors T7, T8, may be designed, for example, for operating cases in which input current I1 is low, for example, is zero, in such a way (for example, by adjusting at least one dimension of a respective gate electrode, in the case of MOSFETs), that a comparison with a comparison current I_Comp-4 takes place, which is associated with the LSB.

In further exemplary specific embodiments, a comparison current for transistors T5, T6 may be adjusted in such a way, for example, with respect to a significance of third comparator unit 110-3 within converter unit 1000, namely, for example, as a second less significant bit, that it corresponds, for example, to double the comparison current I_Comp-4: I_Comp-3=2*I_Comp-4.

As described above by way of example above with reference to FIG. 7, comparator units 110-3, 110-2, 110-1 (for example, in the case of a total of n=4 bit) each have additional circuit components in the form of influencing units 140-3, 140-2, 140-1, which are designed, for example, for influencing the reference current of all less significant bits. In the case of the second, i.e., for example, second less significant bit, this affects the selective diversion of current IVE-3_4 with the aid of influencing unit 140-3, which includes transistors T18, T19. As described above, drain electrode D-T18 of transistor T18 is connected to LSB output 110-4-N or may be acted upon by its output signal AS-4. If the switch or transistor T19 is activated, i.e., is conductively connected, transistors T18, T19 act as a bypass or support for transistor T8 which—together with other transistor T10 of first current mirror unit SP1—provides reference current I_Ref-4 for the fourth, i.e., LSB-, comparator unit 110-4.

As also described above by way of example above with reference to FIG. 7, the further comparator units 110-3, 110-2, 110-1, associated with higher stages of converter unit 1000, in further exemplary specific embodiments operate in a similar manner.

In further exemplary specific embodiments, this therefore results in a linear complexity of the circuit that increases with the number of stages of converter unit 1000.

In further exemplary specific embodiments, a scaling of the width w and/or length L of the gate electrode, for example, of transistors T8, T6, T18, T4, T16, T15, T2, T13, T12, T11 may be used as follows:

T8: w=w1 (for example, w1=85 nanometers, nm), L=L1 (for example, L1=480 nm),
T6, T18: w=w1, L=L1/2,
T4: w=w1, L=L1/4,
T16, T15: w=w2 <=w1, L=L1/4,
T2: w=w1, L=L1/8,
T13, T12, T11: w=w2<=w1, L=L1/8

In further exemplary specific embodiments, a width w and/or a length L of the gate electrode of transistors T1, T3, T5, T7, T9, T10, T20 may be used as follows:

T1, T3, T5, T7: w=w3<=w1, L=L2<L1,
T9: w=w3,L=L2/2,
T10, T20: w=w2<w1, L=L1/4.

In further exemplary specific embodiments, a current intensity for the comparison of a respective stage or comparator unit may be set, for example, individually for each stage, as a result of which the respective comparison current I_Comp-1, I_Comp-2, . . . in further exemplary specific embodiments, for example, may be increased or reduced. In further exemplary specific embodiments, the (bypass) transistors of influencing units 140-1, . . . may in such cases also be similarly adapted to higher stages of converter unit 1000.

In further exemplary specific embodiments, a dimensioning may be carried out, for example, as follows:
1. Transistors T1, T3, T5, T7 are similarly designed,
2. Transistors T8, T6, T4, T2 are scaled in such a way that they output a respective output current as reference current I_Ref-4, I_Ref-3, . . . , which is associated with a weight or a respective stage 110-4 (LSB), 110-3, 110-2, 110-1 (MSB) of converter unit 1000. For example, when converter unit 1000 has a range for input current I1 between 100 nA (nanoamperes) and 1600 nA, transistor T2 associated with the MSB may be set to an output current I_Ref-1 of 800 nA (half the maximum value of input current I1), and transistor T4 to an output current I_Ref-2 of 400 nA, and transistor T6 to an output current I_Ref-3 of 200 nA and transistor T8 to an output current I_Ref-4 of 100 nA.
3. If the transistors of comparator units 110-1, 110-2, . . . are designed as described above by way of example above, the bypass transistors, which are controlled by a respective bit (for the MSB, for example, T11, T12, T13), may have a same ratio of w/L (width to length) of the gate electrode as the respective transistor of the reference current provision unit of the same stage (for example, T2 for the MSB).

In further exemplary specific embodiments, a design of transistors T14, T17, T19 operating, for example, as switches, is relatively flexible, for example, also with respect to a scaling, because transistors T14, T17, T19 are used, for example, only as switches. The voltage drop caused by transistors T14, T17, T19 in further exemplary specific embodiments is compensatable, for example, with the aid of optional transistor T20.

In further exemplary specific embodiments, a design of the respective transistors of the relevant stage may be carried out, for example, based on a maximum current flowing through the respective stage or through comparator unit 110-1, 110-2, 110-3. For example, the transistors may be designed to be larger for larger maximum currents.

In further exemplary specific embodiments, a respective current for a particular comparator unit may be adapted, for example, based on the exemplary configuration above, for example, by scaling, for example, by multiplying the w/L ratio of the respective gate electrodes of the affected transistors of the particular comparator unit, the w/L ratio of the gate electrodes of bypass transistors T11, T12, T13, T15, T16, for example, being correspondingly adaptable. By adapting the current for a particular comparator unit, it is possible in further exemplary specific embodiments, for example, to achieve a balance between a “speed” of the circuit and an electrical power consumption.

In further exemplary specific embodiments, a w/L ratio of the gate electrodes, for example of transistor T9 and/or T10, may be changed, for example, in order to adapt the circuit for another input current range.

In further exemplary specific embodiments, resistances R1, R2, R3, R4 may be optionally provided for the gate electrodes (not designated) of transistors Tl, T3, T5, T7, which may contribute, for example, to a reduction in a tendency to oscillate.

In further exemplary specific embodiments, the circuit depicted by way of example in FIG. 7 (and/or other circuits, for example, implementing the device according to the specific embodiments) may, for example, also be replaced by a circuit inverse thereto, for example, by vertically mirroring and by exchanging all NMOS transistors for PMOS transistors and vice versa (“inversion”).

In further exemplary specific embodiments, at least one output of a comparator unit may be provided with an optional buffer unit or buffer circuit VS-1, VS-2, VS-3, VS-4, which activates, for example, the gate electrodes of switches T14, T17, T19 of a respectively different stage. The provision of buffer circuits VS-1, VS-2, VS-3, VS-4 in further exemplary specific embodiments may increase a stability of the operation and, for example prevent glitches (for example, voltage peaks) or invalid values, for example, input values.

In further exemplary specific embodiments, more or fewer stages than the four stages cited by way of example above may be provided; see also dashed-line block 110-n according to FIG. 7.

Instead of field effect transistors, other types of transistors, for example, bipolar transistors, may be used in further exemplary specific embodiments.

Further exemplary specific embodiments, FIG. 5, relate to a method for operating a device 100, 100a, 100b, 100c including a first comparator unit 110-1 (FIG. 1), first comparator unit 110-1 including a first reference current provision unit 120-1 and a first comparison current provision unit 130-1, the method including: providing 200 (FIG. 5) a first reference current 1_Ref-1 with the aid of first reference current provision unit 120-1, providing 202 a first comparison current I_Comp-1 with the aid of first comparison current provision unit 130-1, comparing 204 first reference current I_Ref-1 with first comparison current I_Comp-1 in order to obtain a first comparison result VE-1 and, based on first comparison result VE-1, influencing 206 at least one reference current I_Ref-2, I_Ref-3, . . . and/or at least one comparison current I_Comp-2, I_Comp-3, . . . of at least one further comparator unit 110-2 and, optionally, outputting 208 a first output signal AS-1 based on first comparison result VE-1.

Further exemplary specific embodiments, FIG. 7, relate to a processing unit 10, for example, for ascertaining a scalar product, for example, a vector matrix multiplier, for example, a dot product engine, including a matrix M of elements including a controllable electrical resistance, and at least one analog-to-digital converter unit 1000a, 1000b, 1000c according to the specific embodiments.

For example, the at least one analog-to-digital converter unit 1000a, 1000b, 1000c according to exemplary specific embodiments may be used for current measurement with respect to at least one column of matrix M, cf. currents 1a, 1b, 1c, in particular on a “high side,” i.e., in the range of a comparatively high electrical potential, for example, of an operating voltage potential varying from a ground potential BP2, cf. voltage source V4.

In further exemplary specific embodiments, processing unit 10 may be used, for example, for machine learning methods (ML) or for applications in the field of artificial intelligence, for example, for hardware accelerators for the training of deep neural networks (DNN).

Further exemplary specific embodiments, FIG. 9, relate to a use 300 of device 100, 100a, 100b, 100c according to the specific embodiments and/or to analog-to-digital converter 1000, 1000a, 1000b, 1000c according to the specific embodiments and/or to a use of the method according to the specific embodiments and/or of processing unit 10 according to the specific embodiments for at least one of the following elements: a) converting 301 a current I1 (FIG. 15) into a binary value AS-AD, b) executing 302 a binary coding, c) providing 303a, for example fully, current-driven analog-to-digital converter.

Information regarding grant and support:
The project leading to this application has received funding from the ECSEL Joint Undertaking (JU) under grant agreement No. 826655. The JU receives support from the European Union's Horizon 2020 research and innovation program, and Belgium, France, Germany, The Netherlands, and Switzerland.

What is claimed is:

1. A device, comprising:
a first comparator unit, the first comparator unit including a first reference current provision unit configured to provide a first reference current, and a first comparison current provision unit configured to provide a first comparison current, the first comparator unit configured to compare the first reference current with the first comparison current to obtain a first comparison result, and, based on the first comparison result, to influence at least one reference current and/or at least one comparison current of at least one further comparator unit.

2. The device as recited in claim 1, further comprising:
at least one first influencing unit configured to influence the at least one reference current and/or the at least one comparison current of the at least one further comparator unit, the at least one first influencing unit including at least one controllable current sink or current source.

3. The device as recited in claim 1, wherein the first comparator unit is configured to output a first output signal based on the first comparison result.

4. The device as recited in claim 1, wherein the first comparator unit is configured to divert at least one predefinable current from a circuit node associated with the at least one reference current and/or the at least one comparison current of at least one further comparator unit based on the first comparison result.

5. The device as recited in claim 1, further comprising:
at least one second comparator unit, the second comparator unit including a second reference current provision unit configured to provide a second reference current, and a second comparison current provision unit configured to provide a second comparison current, the second comparator unit being configured to compare the second reference current with the second comparison current to obtain a second comparison result, and, based on the second comparison result, to influence at least one reference current and/or at least one comparison current of at least one further comparator unit, including to divert based on the second comparison result, at least one predefinable current from a circuit node associated with the at least one reference current and/or with the at least one comparison current of at least one further comparator unit.

6. The device as recited in claim 1, including n number of comparator units, n being greater or equal to 1, each of the n number of comparator units including a reference current provision unit configured to provide a respective reference current and a comparison current provision unit configured to provide a respective comparison current, and each of the n number of comparator units being configured to compare the respective reference current with the respective comparison current to obtain a respective comparison result and, based on the respective comparison result, to output an output signal characterizing the respective comparison result.

7. The device as recited in claim 6, wherein at least some comparator units of the n number of comparator units are configured to compare the respective reference current with the respective comparison current to obtain the respective comparison result, and, based on the respective comparison result, to influence the respective reference current and/or the respective comparison current of at least one further comparator unit.

8. The device as recited in claim 6, wherein a kth comparator unit of the n number of comparator units is configured to influence the respective reference current and/or the respective comparison current of at least one further comparator unit of the n number of comparator units, based on the respective comparison result of the kth comparator.

9. The device as recited in claim 8, wherein the kth comparator unit of the n number of comparator units includes a kth influencing unit, which is configured to influence the respective reference current and/or the respective comparison current of the at least one further comparator unit, the kth influencing unit including a controllable current sink or current source.

10. The device as recited in claim 2, wherein the controllable current sink or current source includes a series connection including at least one first transistor and a semiconductor switch.

11. The device as recited in claim 10, wherein the series connection is connected between a circuit node associated with the at least one reference current and/or the at least one comparison current of the at least one further comparator unit and a reference potential.

12. The device as recited in claim 10, wherein the semiconductor switch is controllable based on the comparison result to activate or deactivate the influencing of the at least one reference current and/or of the at least one comparison current of the at least one further comparator unit.

13. The device as recited in claim 11, wherein the series connection includes a parallel connection made up of first transistors, which is connected in series to the semiconductor switch.

14. The device as recited in claim 13, wherein each first transistor of the parallel connection is assigned to a further comparator unit to divert current from the further comparator unit based on a comparison result of a comparator unit including the parallel connection.

15. The device as recited in claim 10, further comprising:
a compensation unit is provided to compensate for a voltage drop at at least one switch.

16. The device as recited in claim 6, wherein the respective reference current provision unit of the kth comparator unit is part of a first current mirror unit.

17. The device as recited in claim 6, wherein the kth comparison current provision unit is part of a second current mirror unit.

18. An analog-to-digital converter unit, comprising:
at least one device including:
n number of comparator units, n being greater or equal to 1, each of the n number of comparator units including a reference current provision unit configured to provide a respective reference current and a comparison current provision unit configured to provide a respective comparison current, and each of the n number of comparator units being configured to compare the respective reference current with the respective comparison current to obtain a respective comparison result and, based on the respective comparison result, to output an output signal characterizing the respective comparison result;
wherein the converter unit is configured to receive an input current, and, based on the input current, to form a digital output signal.

19. The converter unit as recited in claim 18, wherein the converter unit is configured to, based on a reference current, form an nth reference current using a first current mirror unit, a current intensity of the nth reference current, corresponding to a significance of an nth stage of the converter unit.

20. The converter unit as recited in claim 18, wherein the converter unit is configured to, based on the input current, to form an nth comparison current using a second current mirror unit, a current intensity of the nth comparison current corresponding to a significance of an nth stage of the converter unit.

21. A method for operating a device including a first comparator unit, the first comparator unit including a first reference current provision unit and a first comparison current provision unit, the method comprising:
providing a first reference current using the first reference current provision unit;
providing a first comparison current using the first comparison current provision unit;
comparing the first reference current with the first comparison current to obtain a first comparison result;
based on the first comparison result, influencing at least one reference current and/or at least one comparison current of at least one further comparator unit; and
optionally outputting a first output signal based on the first comparison result.

22. A processing unit configured to ascertain a scalar product, comprising:
a matrix of elements with a controllable electrical resistance; and
at least one analog-to-digital converter unit including:
at least one device including:
n number of comparator units, n being greater or equal to 1, each of the n number of comparator units including a reference current provision unit configured to provide a respective reference current and a comparison current provision unit configured to provide a respective comparison current, and each of the n number of comparator units being configured to compare the respective reference current with the respective comparison current to obtain a respective comparison result and, based on the respective comparison result, to output an output signal characterizing the respective comparison result,;
wherein the converter unit is configured to receive an input current, and, based on the input current, to form a digital output signal.

23. The device as recited in claim 1, wherein the device is used for: a) converting a current into a binary value, or b) executing a binary coding, or c) providing a fully, current-driven analog-to-digital converter.
